(19) United States
(12) Patent Application Publication
(10) Pub. No.: US 2016/0086773 A1
(43) Pub. Date: Mar. 24, 2016

(54) PLASMA PROCESSING APPARATUS

(71) Applicant: Tokyo Electron Limited, Tokyo (JP)

(72) Inventor: Shigeru SENZAKI, Miyagi (JP)

(21) Appl. No.: 14/848,461

(22) Filed: Sep. 9, 2015

(30) Foreign Application Priority Data
Sep. 18, 2014 (JP) 2014-190252

(51) Int. Cl. H01J 37/32

(52) U.S. Cl. CPC H01J 37/32339; H01J 37/32834

(57) ABSTRACT

A plasma processing apparatus includes a reaction chamber for performing a plasma process on a substrate. A pedestal to receive the substrate thereon is provided in the reaction chamber. The reaction chamber includes an area A to generate the plasma therein, an exhaust area, and an area B provided between the area A and the exhaust area. The plasma is generated in the area B. An inner wall of the area A is covered with a first gasifying material. A plurality of partition members made of a second gasifying material is provided downstream of a surface of the substrate on the pedestal so as to divide an inside of the chamber into the area A and the area B to prevent a first particle present in the area B from diffusing into the area A.

### CROSS-REFERENCE TO RELATED APPLICATIONS

This patent application is based upon and claims the benefit of priority of Japanese Patent Application No. 2014-190252, filed on Sep. 18, 2014, the entire contents of which are incorporated herein by reference.

### BACKGROUND OF THE INVENTION

1. Field of the Invention

The present invention relates to a plasma processing apparatus.

2. Description of the Related Art

A plasma processing apparatus is known that performs a plasma process on a semiconductor wafer (which is just referred to as a “wafer” hereinafter) by introducing a gas into a reaction chamber for performing the plasma process and generating plasma by supplying high frequency power to the gas. During the plasma process, particles may occur caused by generated plasma particles that collide with an inner wall of the reaction chamber. In the event that these particles disperse and adhere on the wafer during the plasma process, a problem of a short circuit between interconnections formed in the wafer and the like may occur, which has a bad influence on a yield rate. Therefore, techniques for preventing the particles are proposed as disclosed in Japanese Patent Application Publication No. 8-124912 and Japanese Patent Application Publication No. 2006-303309.

However, recently, a fine processing technology has been developed. As a result, for example, in a process of forming a pattern of 10 nm or smaller, even fine particles of about 0.035 micrometers have a bad influence on the yield rate because of a short circuit between interconnections and the like. Therefore, measures against the fine particles of 0.035 micrometers or smaller that did not affect negatively on the conventional process are needed in the process of the pattern of 10 nanometers or smaller.

Coating a grounded surface in the inner wall of the reaction chamber with a material that does not become particles is considered as one of the measures against the fine particles. However, in this case, when the coating material is an insulating material such as quartz, the plasma does not become stabilized, and the uniformity of plasma decreases. In contrast, when the coating material is a conductive material such as silicon, there is a concern about the cost.

### SUMMARY OF THE INVENTION

Accordingly, in response to the above discussed problems, embodiments of the present invention aim to provide a plasma processing apparatus that stabilizes plasma and prevents particles from scattering across an area above a surface of a substrate placed on a pedestal.

According to one embodiment of the present invention, there is provided a plasma processing apparatus that includes a reaction chamber for performing a plasma process on a substrate by introducing a gas thereinto and generating plasma from the gas by supplying energy of electromagnetic waves to the gas. A pedestal to receive the substrate thereon is provided in the reaction chamber. The reaction chamber includes an area A to generate the plasma therein, an exhaust area, and an area B provided between the area A and the exhaust area formed therein. The plasma is also generated in the area B. An inner wall of the area A is covered with a first gasifying material. A plurality of partition members made of a second gasifying material is provided downstream of a surface of the substrate on the pedestal so as to divide an inside of the chamber into the area A and the area B to prevent a first particle present in the area B from diffusing into the area A and to make a first moving speed of the first particle in the area B higher than a second moving speed of a second particle in the area A.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional view of a plasma processing apparatus according to an embodiment of the present invention;

FIG. 2 is a diagram illustrating a relationship between a partition member and particle tracks according to an embodiment of the present invention;

FIG. 3 is a table illustrating an example of a number of particles when there is a partition member according to embodiments of the present invention;

FIGS. 4A and 4B are diagrams illustrating examples of moving speeds in cases with and without a partition member, respectively;

FIG. 5 is a diagram illustrating an example of an equivalent circuit inside a plasma processing apparatus according to an embodiment of the present invention; and

FIG. 6 is a diagram illustrating patterns of partition members and AC ratios thereof according to an embodiment of the present invention.

### DETAILED DESCRIPTION OF THE PREFERRED EMBODIMENTS

A description is given below of embodiments of the present invention, with reference to accompanying drawings. Note that elements having substantially the same functions or features may be given the same reference numerals and overlapping descriptions thereof may be omitted.

[Overall Configuration of Plasma Processing Apparatus]

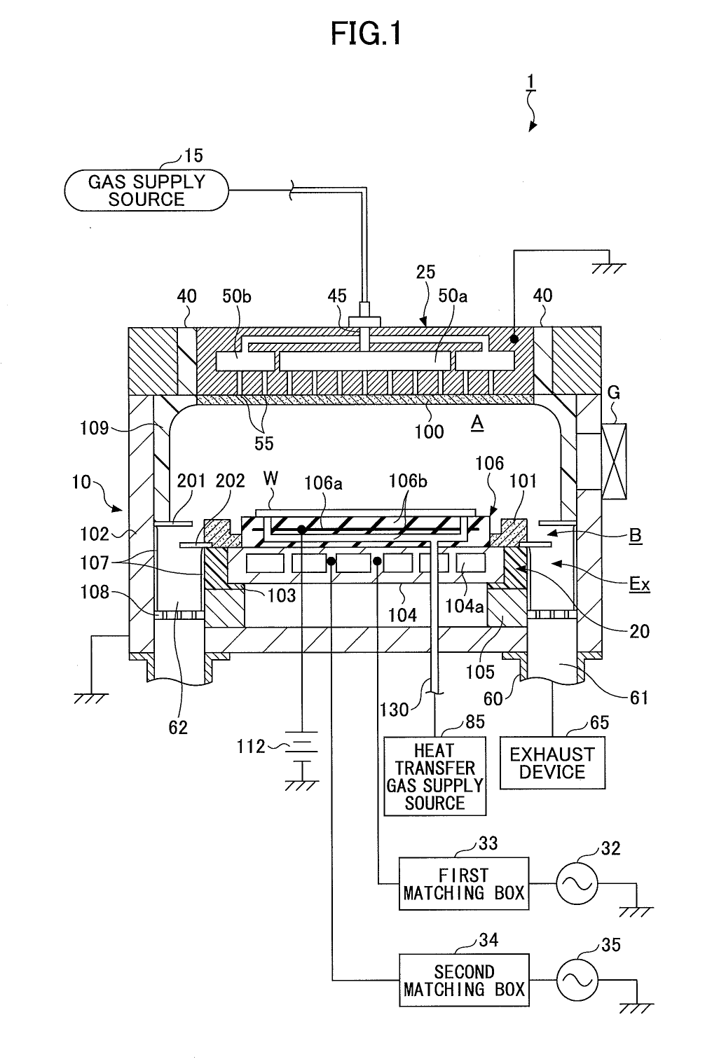

To begin with, a description is given below of a plasma processing apparatus 1 according to an embodiment of the present invention with reference to FIG. 1. In the embodiment, a description is given below of a parallel plate type plasma processing apparatus 1 that includes a lower electrode (i.e., pedestal 20) and an upper electrode 25 (i.e., shower head) disposed parallel to each other inside a reaction chamber 10 and supplies a gas into the reaction chamber 10 from the upper electrode 25 as an example.

The plasma processing apparatus 1 includes the reaction chamber 10 with a surface, for example, made of a conductive material such as alumited (anodized) aluminum and a gas supply source 15 for supplying a gas into the reaction chamber 10. The reaction chamber 10 is connected to the ground. The gas supply source 15 supplies a gas specified for each plasma processing step such as an etching step, a cleaning step and the like.

The reaction chamber 10 is electrically connected to the ground, and includes the pedestal 20 therein for receiving a wafer W thereon. The wafer W is an example of a substrate that is an object subject to a plasma process. The pedestal 20 also functions as the lower electrode. The upper electrode 25 is provided in a ceiling part opposing to the pedestal 20.

An electrostatic chuck 106 for electrostatically attracting the wafer W thereon is provided at an upper surface of the pedestal 20. The electrostatic chuck 106 is configured to have a chuck electrode 106a sandwiched between insulating bodies 106b or surrounded by the insulating body 106b. A direct voltage source 112 is connected to the chuck electrode 106a, and the wafer W is attracted on the electrostatic chuck 106 by Coulomb's force. A focus ring 101 made of, for example, silicon, is disposed in a periphery of the electrostatic chuck 106 to enhance the uniformity of etching process across the surface of the wafer W.

The pedestal 20 is supported by a support 104. A refrigerant passage 104a is formed inside the support 104. For example, cooling water or the like is circulated through the refrigerant passage 104a as a refrigerant depending on the intended use.

A heat transfer gas supply source 85 supplies a heat transfer gas such as helium gas (He) or argon gas (Ar) to aback surface of the wafer W on the electrostatic chuck 106 through a gas supply line 130. Such a configuration allows a temperature of the electrostatic chuck 106 to be controlled by the cooling water flowing through the refrigerant passage 104a and the heat transfer gas supplied to the back surface of the wafer W.

The pedestal 20 is supported by a supporting member 105 through a retaining member 103.

A first high frequency power source 32 that supplies first high frequency power (high frequency power for generating plasma) of a first frequency and a second high frequency power source 35 for supplying second high frequency power (high frequency power for generating a bias voltage) of a second frequency that is lower than the first frequency are connected to the lower electrode (pedestal 20). The first high frequency power source 32 is electrically connected to the lower electrode 20 through a first matching box 33. The second high frequency power source 35 is electrically connected to the lower electrode 20 through a second matching box 34. For example, the first high frequency power source 32 supplies the first high frequency power of 40 MHz. For example, the second high frequency power source 35 supplies the second high frequency power of 3.2 MHz.

Each of the first and second matching boxes 33 and 34 causes load impedance of each of the first and second high frequency power sources 32 and 35, respectively, to match internal (or output) impedance thereof. Each of the first and second matching boxes 33 and 34 functions to cause the load impedance of each of the first and second high frequency power sources 32 and 35, respectively, to appear the same as the internal impedance thereof when plasma is generated at the chamber 10.

Each of the first and second high frequency power sources 32 and 35 is an example of a power source that gives energy of electromagnetic waves to the reaction chamber 10. A microwave power source is cited as another example of a power source that gives the energy of electromagnetic waves to the reaction chamber 10.

The upper electrode 25 is attached to a ceiling part of the chamber 10 by way of a shield ring 40 coating a peripheral side wall thereof. The upper electrode 25 is electrically connected to the ground.

A gas introduction port 45 for introducing a gas from the gas supply source 15 is formed in the upper electrode 25. A diffusion chamber 50a located on a central side and a diffusion chamber 50b located on an edge side for diffusing a gas diverged from the gas introduction port 45 and introduced thereto are provided inside the upper electrode 25.

Many gas supply holes 55 are formed in the upper electrode 25 to supply the gas from the diffusion chambers 50a and 50b into the reaction chamber 10. Each of the gas supply holes 55 supplies the gas to a space between the wafer W placed on the lower electrode 20 and the upper electrode 25.

The gas supplied from the gas supply source 15 is supplied to the diffusion chambers 50a and 50b through the gas introduction port 45. The gas diffuses across each of the diffusion chambers 50a and 50b. Then, the gas is distributed to each of the gas supply holes 55, and introduced toward the lower electrode from the gas supply holes 55. Such a configuration enables the upper electrode 25 to also function as a gas shower head for supplying the gas.

An exhaust pipe 60 forming an exhaust port 61 is provided in a bottom surface of the chamber 10. An exhaust device 65 is connected to the exhaust pipe 60. The exhaust device 65 is constituted of a vacuum pump such as a turbo molecular pump or a dry pump, and reduces the pressure of a processing space inside the reaction chamber 10 to a predetermined degree of vacuum. Moreover, the exhaust device 65 guides the gas in the reaction chamber 10 to an exhaust port 62 and the exhaust port 61 and discharges the gas to the outside. A baffle plate 108 is attached to the exhaust port 62 to control a flow of the gas.

A gate valve G is provided at a side wall 102 of the chamber 10. The gate valve G opens and closes a carry-in/out opening when carrying the wafer in/out of the chamber 10.

A plasma process is performed on the wafer W by the plasma processing apparatus 1 having such a structure. For example, when performing an etching process, to begin with, open and close of the gate valve G is controlled, and then the wafer W is carried in the reaction chamber 10 and placed on the pedestal 20. Next, a gas for etching is introduced into the reaction chamber 10 while first and second high frequency power is supplied to the lower electrode, thereby generating plasma. A desired process such as plasma etching or the like is performed on the wafer by the generated plasma. After the process, the open and close of the gate valve G is controlled, and the wafer W is carried out of the reaction chamber 10.

(Partition Member)

Two partition members 201 and 202 are provided outside the focus ring 101 and between a side wall of the pedestal 2 and the side wall 102 of the reaction chamber 10. Two of the partition members 201 and 202 are made of a material that does not become particles (which is hereinafter referred to as a “gasifying material”). The gasifying material is defined as a member made of a material with properties capable of being evacuated by changing into a gas from a reaction product generated by plasma reaction. In other words, the gasifying material is stripped by action of the plasma and gets mixed in the reaction product. On this occasion, the reaction product contains a volatile substance, which can be exhausted to the outside without being deposited on the inner wall of the reaction chamber 10. Thus, the gasifying material is made of a material that does not become particles. Silicon (Si), quartz, silicon carbide (SiC) and carbon are cited as examples of the gasifying material.

Two of the partition members 201 and 202 may be made of different materials or materials with different properties, or may be made of the same material or a material with the same properties. For example, both of the partition members 201 and 202 may be made of an insulating material or a conductive material. Otherwise, for example, one of the partition members 201 and 202 may be made of an insulating material and the other of the partition members 201 and 202 may be made of a conductive material. Two of the partition members 201 and 202 may be both made of silicon such as the plasma processing apparatus 1 in this embodiment as an example. Otherwise, two of the partition members 201 and 202 may be both made of quartz, or one of the partition members 201 and 202 may be made of quartz and the other may be made of silicon.

The partition members 201 and 202 are arranged on the downstream side of the upper surface of the wafer W placed on the pedestal 20. Each of the partition members 201 and 202 is a ring-shaped flat plate. The partition member 201 is provided in the side wall 102 of the reaction chamber 10 at a downstream position of the upper surface of the wafer W. The partition member 202 is provided at a position in a side surface or a bottom surface of the focus ring 101. Methods of installing the partition members 201 and 202 include screwing or adhering each of the partition members 201 and 202 to an adjacent member, positioning the partition members 201 and 202 horizontally and the like as examples.

In the embodiment, although the partition members 201 and 202 are arranged outside the focus ring 101, the partition members 201 and 202 can be arranged at any positions on the downstream side of the upper surface of the wafer W and on the upstream side of the baffle plate 108 as long as two of the partition members 201 and 202 are arranged at a proper distance (which is hereinafter referred to as a “predetermined distance”) to have an effect of compressing the gas passing through an area B described later.

In the embodiment, the partition member 201 is located outside the partition member 202. The partition member 202 is located on the downstream side of the partition member 201 at the predetermined distance therefrom, and horizontally extends from the inside relative to the partition member 201 up to a position partially facing the partition member 201. In other words, the partition members 201 and 202 are arranged to partially overlap with each other when seen in a plan view. The baffle plate 108 is located at the downstream side of the partition members 201 and 202.

The partition member 201 and the partition member 202 may be arranged in a reverse manner. More specifically, the partition member 201 may be located inside the partition member 202, and at the downstream side of the upper surface of the wafer W and at the upstream side of the partition member 202. Even in this case, each of the partition members 201 and 202 is preferred to extend to a position where the partition members 201 and 202 partially overlap with each other when seen in a plan view.

According to the configuration, a vertical space of the reaction chamber 10 is divided by the partition members 201 and 202. More specifically, in the plasma processing apparatus 1 of the embodiment, the inside of the reaction chamber 10 is divided into a space between the upper surface of the wafer W and the pedestal 20 and the lower surface (ceiling surface) of the upper electrode 25, and an exhaust space on the bottom side of the reaction chamber 10. The space between the upper surface of the wafer W and pedestal 20 and the lower surface (ceiling surface) of the upper electrode 25 is hereinafter referred to as an “area A.” The space divided by the partition member 201 and the partition member 202 is hereinafter referred to as an “area B.” The area A and the area B are spaces where plasma is generated. Moreover, the exhaust space of the exhaust port 62 above the baffle 108 divided by the baffle 108 and divided from the area B by the partition member 202 is hereinafter referred to as an “exhaust area Ex.”

A portion in contact with the area A of the inner wall of the reaction chamber 10 is formed of a gasifying material. More specifically, the ceiling surface in contact with the area A is covered with a gasifying material 100 formed of a silicon plate. The gasifying material 100 is fixed to the upper electrode 25 in contact with the lower surface of the upper electrode 25.

Furthermore, the inner wall surface of the reaction chamber 10 above the upper surface of the partition member 201 and a portion outside the gasifying material 100 of the silicon plate are covered with a gasifying material 109 made of quartz. Thus, the generation of particles inside the area A can be prevented by covering the region surrounding the area A where the plasma is generated with the gasifying materials 100 and 109 made of a material that does not generate particles.

In the embodiment, a portion in contact with the area B and the exhaust area Ex of the side wall 103 of the reaction chamber 10 is covered with a thermal spraying film 107 containing yttria (Y). In addition, a portion in contact with the exhaust area Ex of the side wall of the pedestal 20 is also covered with a thermal spraying film 107 containing yttria. In other words, the thermal spraying film 107 containing yttrium oxide (Y₂O₃) or yttrium fluoride is formed in an area above the baffle 108 and below the partition member 201. By forming the thermal spraying film 107 containing yttria with high plasma resistant properties on the area, the plasma resistant properties of the wall surface of the reaction chamber 10 are enhanced, and the generation of the particles can be minimized. In the embodiment, although the thermal spraying film 107 made of yttria is used, the thermal spraying film 107 may be a film made of a material containing an oxidative metal such as a thermal spraying film made of hafnium oxide, alumite or the like.

Although the embodiment illustrates an example of two of the partition members 201 and 202 horizontally extending from different directions located at the predetermined distance in the vertical direction, the configuration is not limited to the example. For example, three or more partition members may be arranged. A plurality of partition members is preferred to be arranged alternately so as to form the internal space into a meander shape by dividing the internal space by each of the plurality of partition members.

Although the plurality of partition members may be arranged in a form other than the above-mentioned arrangement, the partition member 201 and the partition member 202 are preferably arranged to partially overlap with each other so as to prevent particles present in the area B from recoiling into the area A.

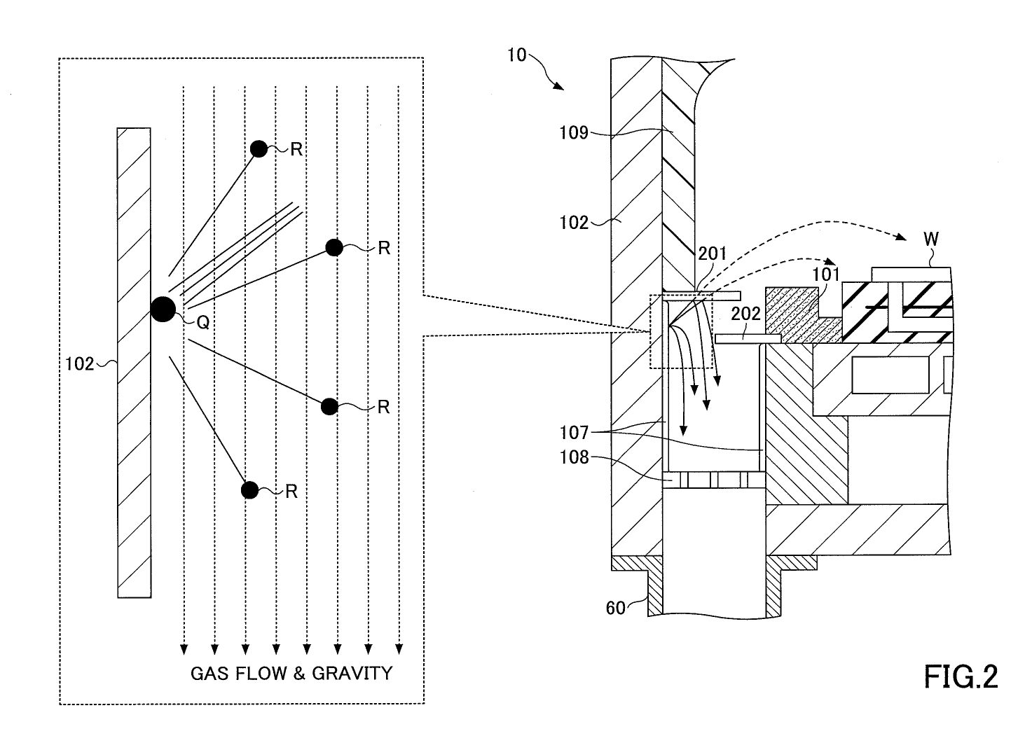

As illustrated in a left-hand figure in FIG. 2, when a particle Q of plasma (ion or the like) collides with the inner wall surface of the reaction chamber 10, a surface substance of the inner wall is stripped off by a physical force of the collision, and the stripped substance scatters over the inside of the reaction chamber as particles R. Because the substance is emitted from the thermal spraying film containing yttria, the particles R in the left-hand figure in FIG. 2 contain yttria.

As illustrated in the left-hand figure in FIG. 2, directions of the particles R change in scattering by being influenced by a downward flow of the gas inside the reaction chamber 10 and the gravity. Furthermore, as illustrated in a right-hand figure in FIG. 2, the particles heading for the area A bounce back from the partition member 201 of the partition member 202. This enables the particles present in the area B not to diffuse into the area A. As a result, the particles present in the area B are exhausted to the outside of the reaction chamber 10 through the exhaust area Ex.

[Examples of Advantageous Effect]

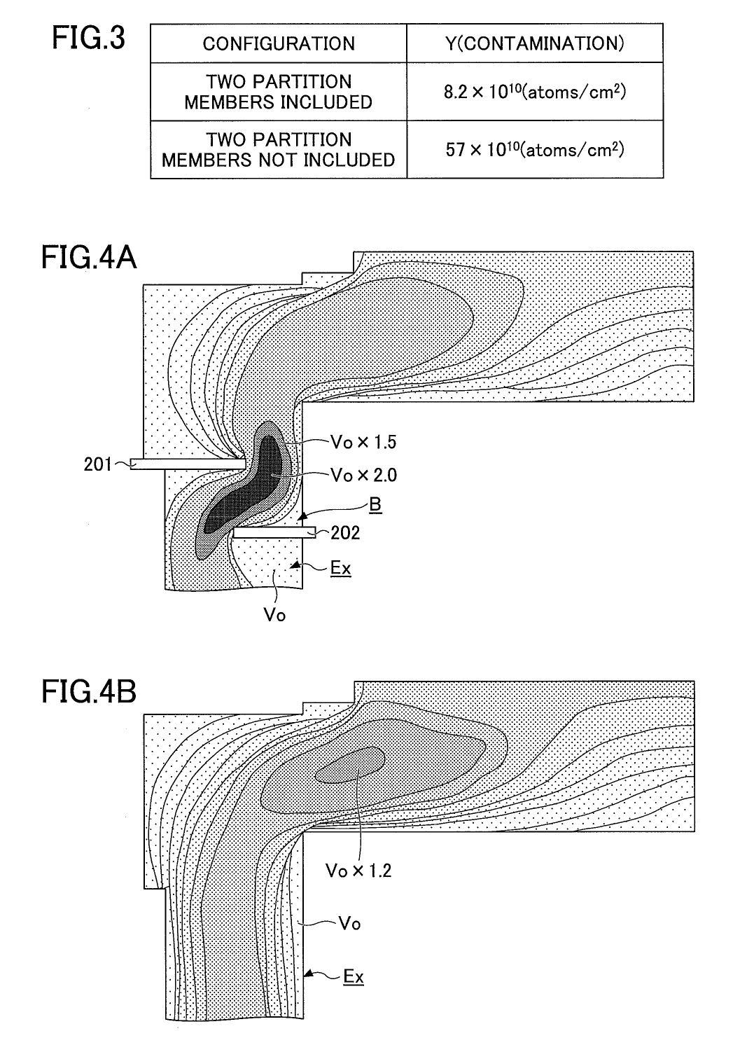

FIG. 3 is a table showing Y components of particles scattered over a wafer W as a result of having performed plasma processes by using the plasma processing apparatus 1 including two of the partition members 201 and 202 according to the embodiment and a plasma processing apparatus not including any partition member. According to the results, as a result of having performed the plasma process by using the plasma processing apparatus 1 including two of the partition members 201 and 202, the contamination in the Y direction of the particles having scattered over the wafer W was “8.2×10¹⁰ atoms/cm².”

In contrast, as a result of having performed a plasma process by using the plasma processing apparatus configured to have the same structure as the plasma processing apparatus 1 except for having a partition member was not included, the contamination in the Y direction of the particles having scattered over the wafer W was “57×10¹⁰ atoms/cm².” The results indicate that the plasma processing apparatus 1 with two of the partition members 201 and 202 was able to reduce the value of contamination in the Y direction to 1/7 relative to the value of the contamination of the plasma processing apparatus without the partition members 201 and 202.

Considering that the area A was covered with the gasifying materials 100 and 109 and particles were not generated in the area A, from the above results, it is thought that the contamination of “8.2×10¹⁰ atoms/cm²” in the Y direction was caused by the particles scattered from the exhaust area Ex. Hence, in the plasma processing apparatus 1, the partition members 201 and 202 are arranged so that the partition members 201 and 202 can enhance an effect of blocking a path of the particles generated from the inner wall surface of the reaction chamber 10 and scattering over the wafer W.

FIG. 4A illustrates an example of moving speeds of particles in the area B and the exhaust area Ex as a result of the partition members 201 and 202. FIG. 4B illustrates moving speeds of particles in the area B and the exhaust area Ex when not including the partition members 201 and 202. As discussed above, the particles stripped from the inner wall surface of the reaction chamber 10 scatter over the wafer W against the flow of gravity and gas. Thus, as illustrated in FIG. 4A, the number of particles scattering over the wafer W can be reduced by setting the moving speed of the particles in the area B that is narrowed down by providing the partition members 201 and 202 at one-and-a-half to two times as much as a moving speed Vo of the particles in the exhaust area Ex.

In contrast, as illustrated in FIG. 4B, when the partition member 201 and 202 are not included, the moving speed in an area corresponding to the area B becomes 1.2 times as much as the moving speed Vo in an area corresponding to the exhaust area Ex. The results indicate that the plasma processing apparatus 1 including the partition members 201 and 202 can effectively prevent the particles scattering over the wafer W.

The plasma processing apparatus 1 of the embodiment prevents the particles from being generated from the area A in which the particles have the most influence on the wafer W during the plasma process, by covering the area A with the gasifying materials 100 and 109 such as silicon or quartz. On the other hand, with respect to the area B and the exhaust area Ex, the generation of the particles can be minimized by covering the area B and the exhaust area Ex with a material containing an oxidative metal such as the thermal spraying film 107 containing yttria, or a thermal spraying film made of hafnium oxide, alumite or the like without using silicon or quartz while considering the cost and issues described later.

As described above, the space of area B can be formed by providing the partition members 201 and 202 between the area A and the exhaust area Ex. This particularly prevents the area A from being contaminated by the particles containing yttria in the area B among particles, compared to the conventional plasma processing apparatuses.

Recently, the microfabrication of substrates has been developed, and for example, in a process for forming a pattern of 10 nm or smaller, even very fine particles of about 0.35 micrometers that did not cause any problem can negatively affect a yield rate. Hence, to perform a process for forming a pattern of 10 nanometers or smaller, measures against very fine particles that did not cause any problem conventionally are needed. In particular, metal such as yttria have a bad effect on the yield rate because the metal short-circuits interconnections and the like. Therefore, in the embodiment, the number of particles scattering over the wafer W placed on the pedestal 20 during the plasma process can be reduced to a very small number by covering the area A of the inner wall surface of the reaction chamber 10 with the gasifying materials 100 and 109 and providing the partition members 201 and 202 in the area B.

[Effects Due to AC Ratio]

In an embodiment, by selecting a material of the partition member 201 and 202 such that an anode/cathode ratio (which is hereinafter referred to as an “AC ratio”) is in a predetermined value range, further reduction of the particles is achieved.

In order to prevent the inner wall from being stripped off, the AC ratio only has to be increased. The AC ratio shows asymmetry between anode electrodes and cathode electrodes, and an anode-side voltage Va (high frequency voltage) and a cathode-side voltage Vc (high frequency voltage) are capacitively distributed to an anode-side capacitance Ca and a cathode-side capacitance Cc thereby. More specifically, a ratio of the cathode-side voltage Vc to the anode-side voltage Va is expressed by the following formula (1).

AC ratio=Ca/Cc=Vc/Va (1)

The AC ratio is the anode-side capacitance Ca relative to the cathode-side capacitance Cc and can be expressed by a ratio of an area on the anode side relative to an area on the cathode side. Thus, by increasing the AC ratio by increasing the area on the anode side relative to the area on the cathode side, it is possible to keep the anode-side voltage Va low, to reduce a sputtering force against the inner surface wall of the reaction chamber 10 on the anode side, and to decrease the generation of particles.

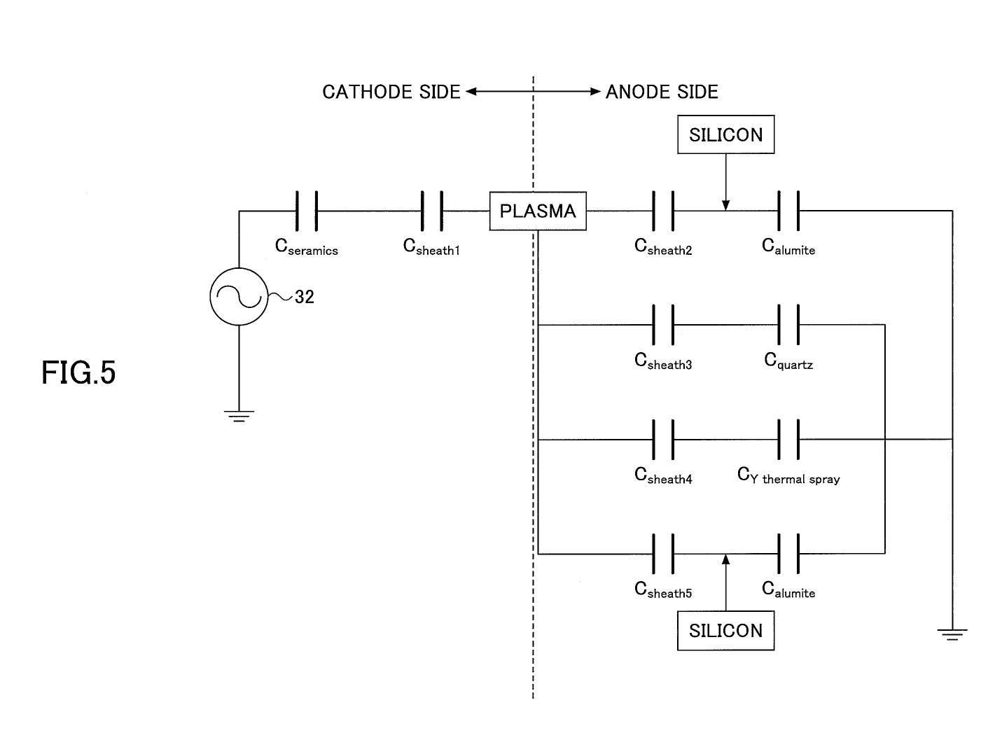

FIG. 5 is an equivalent circuit illustrating the anode-side capacitance Ca and the cathode-side capacitance Cc with respect to the generated plasma. The cathode-side capacitance Cc is the sum of a capacitance C_{ceramics} generated at the pedestal 20 and a sheath capacitance Cₛₕₑₐₜₕ₁ of the surface of the pedestal 20.

The anode-side capacitance Ca is the sum of a capacitance Cₐₗᵤₘᵢₜₑ generated at the upper electrode 25, a sheath capacitance Cₛₕₑₐₜₕ₂ of the surface of the gasifying material 100 made of silicon, a capacitance C_{quartz} generated at the gasifying material 109 made of quartz, a sheath capacitance Cₛₕₑₐₜₕ₃ of the surface of the gasifying material 100, a capacitance C_{Y thermal spray} generated at the thermal spraying film 107 containing yttria, a sheath capacitance Cₛₕₑₐₜₕ₄ of the surface of the thermal spraying film 107, a capacitance Cₐₗᵤₘᵢₜₑ generated at the partition member 201 and 202, and a sheath capacitance Cₛₕₑₐₜₕ₅ of the surface of the partition members 201 and 202.

In this manner, in the embodiment, by providing the partition members 201 and 202 forming a grounded surface, the capacitance Cₐₗᵤₘᵢₜₑ generated at the partition members 201 and 202 and the sheath capacitance Cₛₕₑₐₜₕ₅ are added to the anode-side capacitance Ca. This serves to increase the AC ratio. As a result, a sheath voltage on the anode side can be effectively kept low; the sputtering force is reduced; and the generation of the particles of yttria can be reduced.

As described above, the plasma processing apparatus 1 of the embodiment prevents the generation and diffusion of the particles by using the gasifying materials 100 and 109 that do not become particles in the area (area A) above the surface of the wafer W placed on the pedestal 20.

On the other hand, the thermal spraying film 107 containing yttria is used in the area located lower than the surface of the wafer W placed on the pedestal 20, as a material that is less expensive than the gasifying materials 100 and 109. In addition to this, the partition members 201 and 202 are disposed so as not to scatter the particles over the surface of the wafer W. This makes it possible to prevent the diffusion of particles and to reduce the cost.

Moreover, the plasma processing apparatus 1 of the embodiment can increase the AC ratio by using silicon of a conductive material as the partition members 201 and 202, which can stabilize the plasma.

[Material of Partition Members and AC Ratio]

When using a conductive material such as silicon in the partition members 201 and 202, there is a concern about the cost compared to an insulating material such as quartz and the like. On the other hand, when covering the inner wall surface of the reaction chamber 10 with quartz up to the surroundings of the baffle 108, the AC ratio becomes small. When the AC ratio becomes small, an impact of ions on the wafer W placed on the cathode side becomes small and the plasma becomes difficult to be ignited. Hence, the AC ratio is preferred to be increased while keeping the cost down by using the gasifying material 100 made of silicon in the ceiling part and the gasifying material 109 made of quartz in the side wall.

By increasing the AC ratio, the impact of the ions on the wafer W placed on the cathode side becomes great. Moreover, the plasma becomes easy to be ignited. Furthermore, because an impact of the ions on the wall surface and the like on the anode side becomes small, the generation of particles can be further reduced. In particular, by reducing the generation of particles of yttria, the metal contamination in the reaction chamber 10 can be prevented, and the yield rate of the process forming a pattern of 10 nanometers or smaller can be improved.

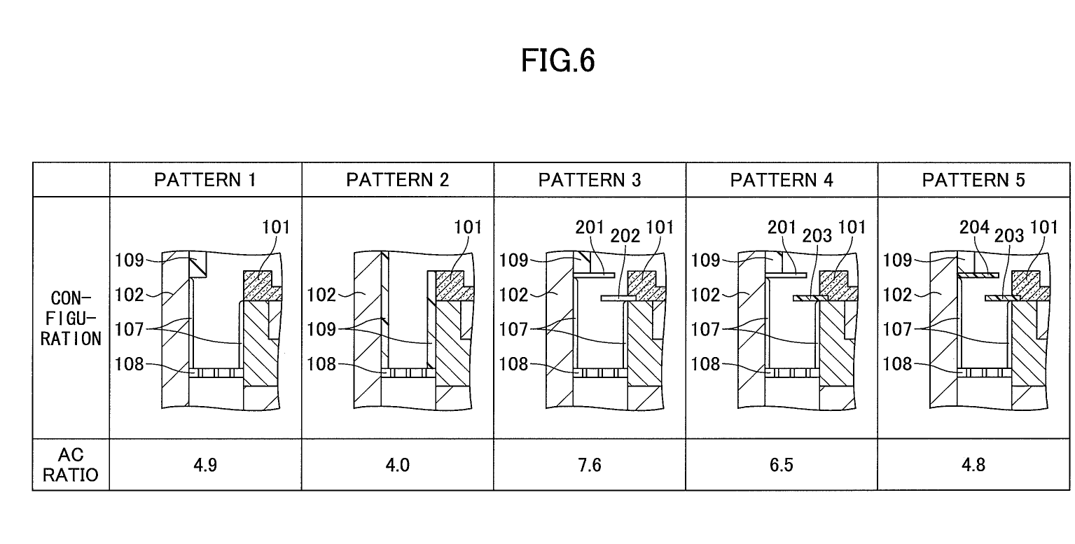

In the plasma processing apparatus 1 that can achieve such effects, an examination was performed of how much the AC ratio changes when replacing the material of the partition members 201 and 202 by silicon or quartz. FIG. 6 shows the examination results. Hereinafter, the thermal spraying film 107 may be formed of a material containing an oxidative metal such as hafnium oxide, alumite and the like.

A pattern 1 in FIG. 6 is a pattern including an area corresponding to the area B and the exhaust area Ex of the embodiment covered with the thermal spraying film 107 containing yttria without a partition member. A pattern 2 in FIG. 6 is a pattern including an area corresponding to the area B and the exhaust area Ex covered with the gasifying material 109 made of quartz without a partition member.

A pattern 3 in FIG. 6 is a pattern of the embodiment. More specifically, the pattern 3 included the partition member 201 and 202, and the region of the area B and the exhaust area Ex was covered with the thermal spraying film 107 containing yttria. The upper partition member 201 was made of silicon, and the lower partition member 202 was made of quartz.

A pattern 5 in FIG. 6 is a pattern similar to the pattern 4. More specifically, the pattern 5 included partition members 203 and 204, and the region of the area B and the exhaust area Ex was covered with the thermal spraying film 107 containing yttria. The upper and lower partition members 203 and 204 were both made of quartz.

According to the examination results, the AC ratio of pattern 1 was “4.9”; the AC ratio of pattern 2 was “4.0”; the AC ratio of pattern 3 was “7.6”; the AC ratio of pattern 4 was “6.5”; and the AC ratio of pattern 5 was “4.8.” Hence, the results indicate that the AC ratio increased and that the particles of yttria could be minimized when using silicon in the partition members 201 and 202. In addition, the results indicate that even when one of the partition members 201 and 202 was made of silicon and the other partition member 202 was made of quartz, although the AC ratio was lower than the case where both of the partition members 201 and 202 were made of silicon, the AC ratio was larger than the patterns 1, 2 and 5 and the particles of yttria could be reduced.

As described above, according to the plasma processing apparatus 1 of the embodiments, the particles can be prevented from scattering across an area above the surface of the wafer W placed on the pedestal 20 while stabilizing the plasma by providing the partition members 201 and 202 made of silicon and the like.

In particular, according to the plasma processing apparatus 1 of the embodiments, the particles of yttria can be reduced to about 1/7 compared to the conventional plasma processing apparatus. This makes it possible to cope with very fine particles of yttria of about 0.035 micrometers so as to prevent the yield rate from decreasing.

Here, it is acknowledged that the plasma processing apparatus 1 of the embodiments can perform a plasma process in a pressure range under which the conventional plasma processing apparatus without the partition members 201 and 202 performed the plasma process as a result of PQ characteristic comparison.

In this manner, according to the embodiments of the present invention, a plasma processing apparatus can prevent particles scattering across an area above a surface of a wafer placed on a pedestal while stabilizing plasma.

Hereinabove, although the plasma processing apparatus has been described according to the embodiments, the plasma processing apparatus of the present invention is not limited to the embodiments and various modifications and improvements can be made without departing from the scope of the invention. Moreover, the embodiments and modifications can be combined as long as they are not contradictory to each other.

For example, the plasma processing apparatus of the present invention may be applied not only to a capacitively coupled plasma (CCP: Capacitively Coupled Plasma) apparatus but also to other types of plasma processing apparatuses. For example, the other types of plasma processing apparatus includes an inductively coupled plasma (ICP: Inductively Coupled Plasma) apparatus, a helicon wave excited plasma (HWP: Helicon Wave Plasma) apparatus, an electron cyclotron resonance plasma (ECR: Electron Cyclotron Resonance Plasma) apparatus and the like as examples.

A substrate to be processed in the plasma processing apparatus of the present invention is not limited to the wafer, but for example, may be a large substrate for a flat panel display, a substrate for an EL (electroluminescence) device or a solar cell.

What is claimed is:

1. A plasma processing apparatus comprising:
a reaction chamber for performing a plasma process on a substrate by introducing a gas thereinto and generating plasma from the gas by supplying energy of electromagnetic waves to the gas;
a pedestal to receive the substrate thereon provided in the reaction chamber;
an area A to generate the plasma therein formed in the reaction chamber;
an exhaust area formed in the reaction chamber;
an area B provided between the area A and the exhaust area formed in the reaction chamber, the plasma being generated in the area B;
a first gasifying material covering an inner wall of the area A;
a plurality of partition members made of a second gasifying material provided downstream of a surface of the substrate on the pedestal so as to divide an inside of the chamber into the area A and the area B to prevent a first particle present in the area B from diffusing into the area A and to make a first moving speed of the first particle in the area B higher than a second moving speed of a second particle in the area A.

2. The plasma processing apparatus as claimed in claim 1, wherein the first moving speed of the first particle in the area B is one-and-a-half to two times as much as the second moving speed of the second particle in the area A.

3. The plasma processing apparatus as claimed in claim 1, wherein the plurality of partition members are provided at a position to prevent the first particle present in the area B from recoiling into the area A.

4. The plasma processing apparatus as claimed in claim 1,
wherein the plurality of partition members are two flat plates, and
both of the flat plates are made of an insulating material or an conductive material, or
one of the flat plates is made of the insulating material and the other of the flat plates is made of the conductive material.

5. The plasma processing apparatus as claimed in claim 4, further comprising:
an anode provided in an upper part of the reaction chamber facing the pedestal, the anode having a first capacitance,
wherein the pedestal functions as a cathode having a second capacitance, and the plurality of partition members is provided to set a ratio of the first capacitance of the anode to the second capacitance of the cathode in a predetermined range.

6. The plasma processing apparatus as claimed in claim 1, wherein the area B is covered with a material containing yttria.

7. The plasma processing apparatus as claimed in claim 1, wherein the plurality of partition members are provided to divide the area B from the exhaust area.

8. The plasma processing apparatus as claimed in claim 7, wherein the plurality of partition members are provided at a distance from each other in a vertical direction.

9. The plasma processing apparatus as claimed in claim 8, wherein one the plurality of partition members horizontally extends from a first portion and the other of the plurality of the partition members extends from a second portion located opposite to the first portion in a plan view so as to partially overlap with each other and to form a meander-shaped exhaust passage in the vertical direction.

10. The plasma processing apparatus as claimed in claim 9, wherein the first portion is provided in an inner side wall of the reaction chamber and the second portion is provided in an outer side wall of the pedestal.

11. The plasma processing apparatus as claimed in claim 10, wherein the plurality of the partition members has an annular plate-like shape.
